(19) United States
(12) Patent Application Publication
(10) Pub. No.: US 2007/0163500 A1
(43) Pub. Date: Jul. 19, 2007

(54) Rectangular planar-type ICP antenna having balanced ratio of magnetic field and electric potential

(76) Inventors: Tae-Un Kim, Cheju-si (KR); Se-Jin Lee, Seoul (KR); Kyung-Hwan Jang, Suwon-si (KR); Seung-Ho Lee, Suwon-si (KR); Jeong-Beom Ryeo, Seoul (KR)

Correspondence Address: Eric D. Cohen, 22nd Floor, 120 South Riverside Plaza, Chicago, IL, 60606-3945, US

(21) Appl. No.: 11/483,894

(22) Filed: Jul. 10, 2006

(30) Foreign Application Priority Data
Jan. 17, 2006 (KR) 10-2006-0004906

(51) Int. Cl. C23C 16/00

(52) U.S. Cl. 118/723 I

(57) ABSTRACT

The rectangular planar-type ICP (Inductively Coupled Plasma) antenna having a balanced ratio of a magnetic field and an electric potential is capable of improving uniformity of plasma as well as improving a density of plasma. The planar-type ICP antenna includes first and second antenna elements spirally shaped outwards from an end thereof, respectively. The ends of the fist and second antenna elements are interconnected by means of a grounded common terminal. A RF power source is connected to a powered common terminal for connecting first and second powered terminals that are the other ends of the first and second antenna elements. The first and second powered terminals are arranged in peripheral portions of the antenna and the grounded common terminal is arranged in a center portion of the antenna in order to compensate for a drop of plasma ion flux in a region to which power is applied.

### BACKGROUND OF THE INVENTION

1. Field of the Invention

The present invention relates to rectangular a planar-type ICP (Inductively Coupled Plasma) antenna having a balanced ratio of a magnetic field and an electric potential, and more particularly to a rectangular planar-type ICP antenna capable of improving uniformity of plasma as well as preventing weakening of plasma in center and corner regions, which was a problem in treating a glass substrate for a large-sized FPD.

2. Description of the Related Art

Generally, plasma generators are classified into an ICP (Inductive Coupled Plasma) generator, a CCP (Capacitively Coupled Plasma) generator, a microwave plasma generator and so on. Among them, the ICP generator is widely used since it may generate a high-density plasma under a low operation pressure.

The ICP generator includes a chamber 11, a gas injection unit (not shown) for injecting a reaction gas into the chamber 11, a vacuum pump 13 for making the chamber 11 vacuous before the reaction gas is injected thereto, an antenna 15 mounted to an upper portion of dielectric substance 14, a power supply 17 for supplying power to the antenna 15, a RF power source 17 for supplying power to the antenna 15, and a chuck 19 to which a substrate 20 to be processed is mounted, as shown in FIG. 1.

The antenna 15 is spirally shaped as shown in FIG. 2, and it is connected to the power source at its center point 15a and grounded at both ends 15b.

If power is supplied to the antenna 15, a magnetic field changing along with time is formed in a direction perpendicular to the plane formed by the antenna 15, and this magnetic field forms an inductive electric field in the chamber 11. This inductive electric field heats electrons to generate a plasma inductively coupled with the antenna 15. This plasma is used for etching or deposition of a substrate. Meanwhile, if a separate bias power 18 is applied to the chuck 19, it is possible to control the energy of plasma input to the substrate 20. Reference numerals 17a and 18a respectively designate impedance matching circuits, and reference numeral 10 designates an ICP generator.

However, in the antenna 15, a plasma density in the center portion 15a to which power is applied is lowered and a plasma density in peripheral portions is increased, and also an electron temperature is high in the center portion and lowered in the peripheral portions, due to a drop of plasma ion flux. Since the electron temperature is high in the center portion, the plasma in the center portion is scattered out. In addition, since a temperature of the glass surface in the peripheral portions is high, an etch rate by plasma is faster in the peripheral portions than in the center portion.

In order to solve the above problems, it is required to increase density and temperature of plasma as a whole and also improve uniformity of plasma and uniformity of electron temperature in the center portion and the peripheral portions.

### SUMMARY OF THE INVENTION

The rectangular planar-type ICP (Inductively Coupled Plasma) antenna having a balanced ratio of a magnetic field and an electron potential according to the present invention is designed to solve the problems of the prior art, and therefore it is an object of the present invention to provide a planar-type ICP antenna capable of increasing density and temperature of plasma as a whole, and also improving uniformity of plasma and uniformity of electron temperature in a center portion and peripheral portions thereof.

In order to accomplish the above object, the present invention provides a planar-type ICP (Inductively Coupled Plasma) antenna having a balanced ratio of a magnetic field and an electric potential, which includes a first antenna element spirally shaped outwards from an end thereof; and a second antenna element spirally shaped outwards from an end thereof, wherein the ends of the fist and second antenna elements are interconnected by means of a grounded common terminal that is grounded by a ground strip, wherein a RF (Radio Frequency) power source is connected to a powered common terminal for connecting first and second powered terminals that are the other ends of the first and second antenna elements, and wherein the first and second powered terminals are arranged in peripheral portions of the antenna and the grounded common terminal is arranged in a center portion of the antenna in order to compensate for a drop of plasma ion flux in a region to which power is applied.

In another aspect of the present invention, there is also provided a planar-type ICP antenna having a balanced ratio of a magnetic field and an electric potential, which includes a first antenna element spirally shaped outwards from a first ground terminal that is an end thereof, and a second antenna element spirally shaped outwards from a second ground terminal that is an end thereof, wherein the first and second ground terminals are respectively grounded by means of a ground strip, wherein a RF power source is connected to a powered common terminal for connecting first and second powered terminals that are the other ends of the first and second antenna elements, and wherein the first and second powered terminals are arranged in peripheral portions of the antenna and the first and second ground terminals are arranged in a center portion of the antenna in order to compensate for a drop of plasma ion flux in a region to which the RF power source is applied.

Preferably, a capacitor is installed to the ground terminal so as to make an electric potential energy applied to the entire antenna uniform and optimize a phase difference of current and voltage.

Preferably, the ground strip is perpendicular to a plane formed by the first and second antenna elements, and the ground strip is connected to a ground strip of an impedance matching circuit or a ground strip of a chamber wall.

Preferably, the first and second antenna elements respectively have a plurality of serial regions and a plurality of parallel regions.

Preferably, the peripheral portions are changed into a serial region at corners of the antenna.

Preferably, the powered terminals are positioned at sides of the antenna.

### BRIEF DESCRIPTION OF THE DRAWINGS

FIG. 1 is a sectional view showing an ICP (Inductively Coupled Plasma) generator having a conventional ICP antenna;

FIG. 2 is a plane view showing the ICP antenna of FIG. 1;

FIG. 3 is a plane view showing an ICP antenna according to a preferred embodiment of the present invention;

FIG. 4 is a sectional view showing a plasma generator to which the ICP antenna of FIG. 3 is installed;

FIG. 5 is a perspective view showing an ICP antenna according to a second embodiment of the present invention;

FIG. 6 is a perspective view showing an ICP antenna according to a third embodiment of the present invention;

FIG. 7 is a plane view showing an ICP antenna according to a fourth embodiment of the present invention;

FIG. 8 is a plane view showing an ICP antenna according to a fifth embodiment of the present invention;

FIG. 9 shows an etch rate in case of etching a glass using the plasma generator of FIG. 1;

FIG. 10 shows an etch rate in case of etching a glass using the plasma generator of FIG. 3;

FIG. 11 shows a plasma density distribution in case of etching a glass using the plasma generator of FIG. 1; and

FIG. 12 shows a plasma density distribution in case of etching a glass using the plasma generator of FIG. 3.

### DESCRIPTION OF THE PREFERRED EMBODIMENT

Hereinafter, preferred embodiments of the present invention will be described in detail referring to the accompanying drawings. Prior to the description, it should be understood that the terms used in the specification and appended claims should not be construed as limited to general and dictionary meanings, but interpreted based on the meanings and concepts corresponding to technical aspects of the present invention on the basis of the principle that the inventor is allowed to define terms appropriately for the best explanation. Therefore, the description proposed herein is just a preferable example for the purpose of illustrations only, not intended to limit the scope of the invention, so it should be understood that other equivalents and modifications could be made thereto without departing from the spirit and scope of the invention.

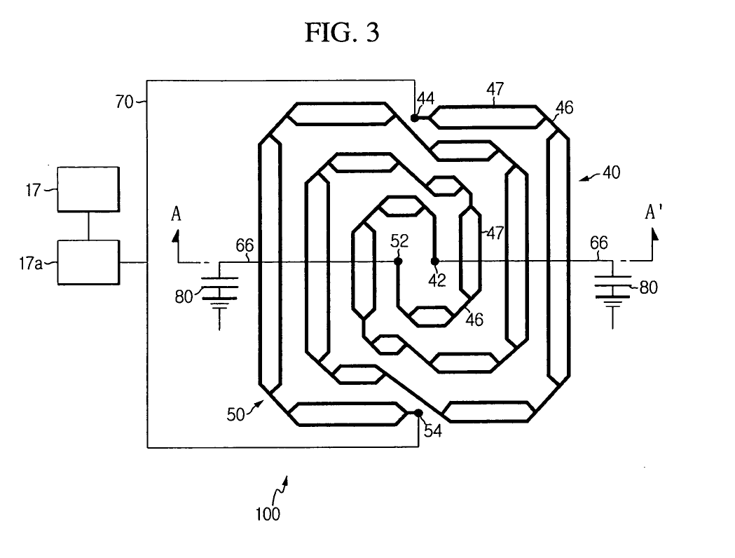

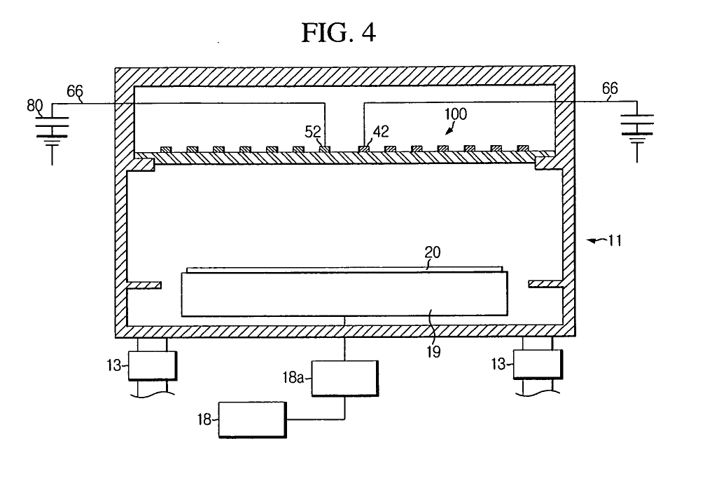

FIG. 3 is a plane view showing an ICP (Inductively Coupled Plasma) antenna according to a first embodiment of the present invention, and FIG. 4 is a sectional view showing a plasma generator to which the above antenna is installed.

Referring to FIGS. 3 and 4, the antenna 100 includes a first antenna element 40 spirally shaped outwards from its end, namely a first ground terminal 42, and a second antenna element 50 spirally shaped outwards from its end, namely a second ground terminal 52. Meanwhile, FIG. 4 shows the antenna 100 taken along the line A-A′ of FIG. 3, so first and second powered terminals 44, 54, a powered common terminal 70, a RF power source 17 and an impedance matching circuit 17a are not shown in FIG. 4. Preferably, the antenna 100 has a rectangular shape.

Spirals of the first antenna element 40 and the second antenna element 50 are rotated in the same direction in parallel. Though it is illustrated in the drawings that the first and second antenna elements 40, 50 are rotated in a counterclockwise direction, the first and second antennas may also be rotated in a clockwise direction.

The first and second antenna elements 40, 50 have a plurality of serial regions 46 and a plurality of parallel regions 47. The plurality of parallel regions 47 are used for flowing electric current divisionally so as to generate plasma more uniformly.

The first and second ground terminals 42, 52 are respectively grounded by means of ground strips 66. The first and second ground terminals 42, 52 are spaced apart from each other by a predetermined distance. Preferably, a capacitor 80 is installed to the ground strip 66. The capacitor 80 is installed for allowing the voltage applied to the entire antenna 100 to be uniform, and for minimizing a phase difference of current and voltage. The capacitor 80 is a common one used for condensing electricity. Though it is illustrated that the capacitor 80 is installed to the ground strip 66, the capacitor 80 may be installed to a predetermined position of the first and second antenna elements 40, 50.

Preferably, the capacitor 80 has a withstanding voltage of about several hundred volts to 15 kV and a withstanding current of several amperes to several hundred amperes in consideration of the intensity of the applied RF power source 17 and the entire configuration of the antenna 100. In addition, the condensing ability of the capacitor 80 has a capacity of a several PF to several thousand PF in consideration of size and shape of the antenna 100.

In addition, the ground strips 66 are connected to a ground strip (not shown) of the impedance matching circuit 17a or a ground strip (not shown) of a wall of the chamber 11, with being perpendicular to the plane formed by the first and second antenna elements 40, 50.

A first powered terminal 44 and a second powered terminal 54 are interconnected by means of a powered common terminal 70. The powered common terminal 70 is installed to pass above the first and second antenna elements 40, 50. The RF power source 17 is connected to the powered common terminal 70. Thus, in the antenna 100, the RF power source 17 is applied through the power common terminal 70 and the first and second powered terminals 44, 54. That is to say, the first and second antenna elements 40, 50 are connected to the same RF power source 17 in parallel.

As mentioned above, in order to compensate for a drop of plasma ion flux in the portion to which the RF power source 17 is applied, the first and second powered terminals 44, 54 are arranged in peripheral portions of the antenna 100, and the first and second ground terminals 42, 52 are arranged in a center portion of the antenna 100. Since a plasma density in the center portion of the antenna 100 may be increased, it is possible to conduct uniform etching.

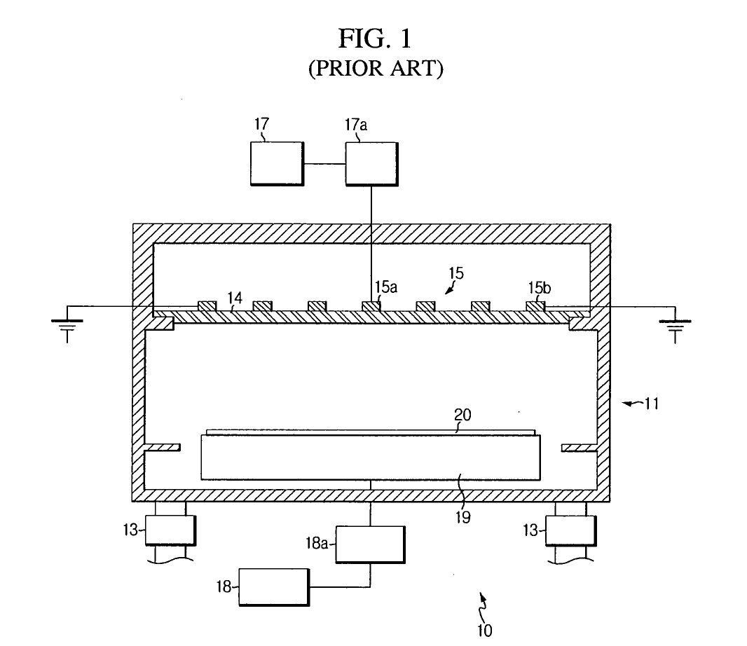

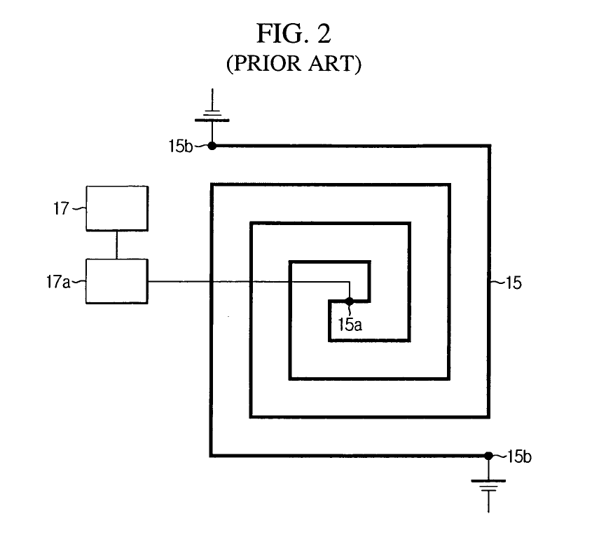

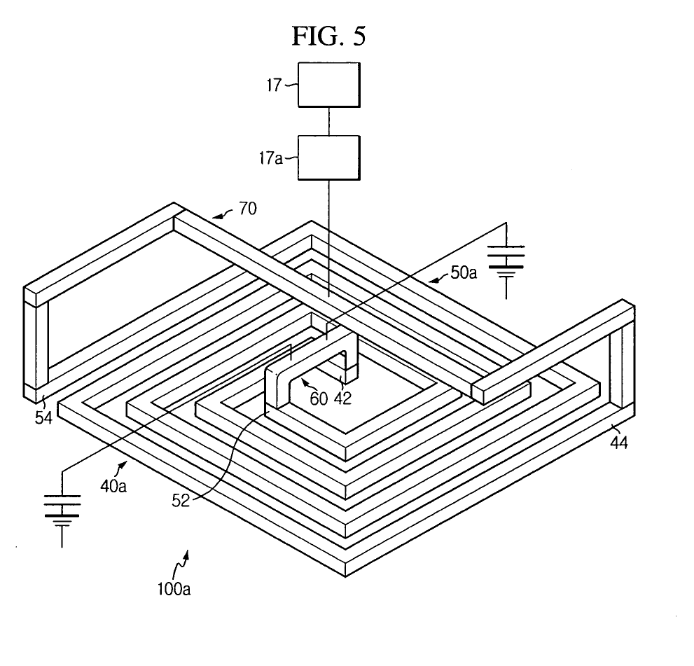

FIG. 5 shows an antenna according to a second embodiment of the present invention. In FIG. 5, the same reference numeral as in FIGS. 1 to 4 designates the same component having the same function.

The antenna 100a is composed of first and second antenna elements 40a, 50a, and a ground terminal 42, 52 of each antenna element 40a, 50a is positioned at a center portion of the antenna 100a and grounded. In addition, a powered terminal 44, 54 of each antennal element 40a, 50a is positioned in peripheral portions of the antenna 100a and connected to a RF power source 17.

Meanwhile, though it is illustrated that the first and second powered terminals 44, 54 are positioned at corners, it is also possible that the first and second powered terminals are positioned on a side between corners.

In the above antenna 100a, the first and second ground terminals 42, 52 are connected by means of a grounded common terminal 60. The grounded common terminal 60 is bent so that its center portion is protruded upward. Preferably, the grounded common terminal 60 has an inverted U shape.

A ground strip 66 is connected to the grounded common terminal 60. Preferably, two ground strips 66 are respectively connected to the grounded common terminal 60.

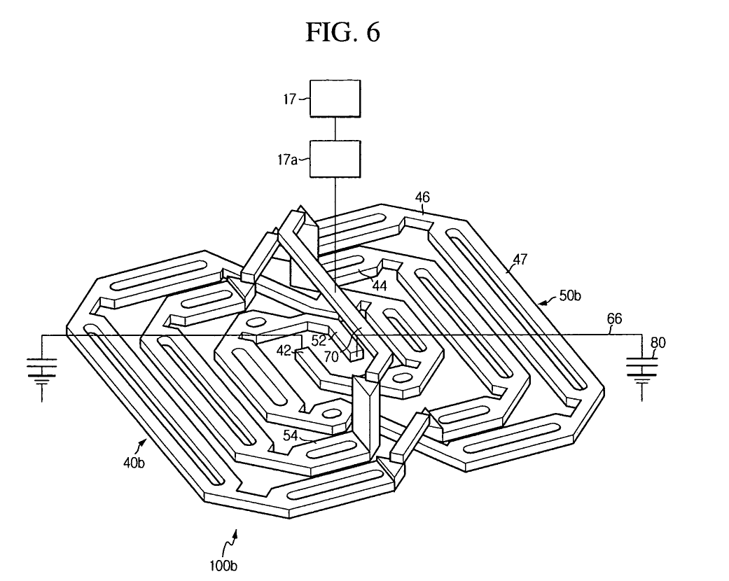

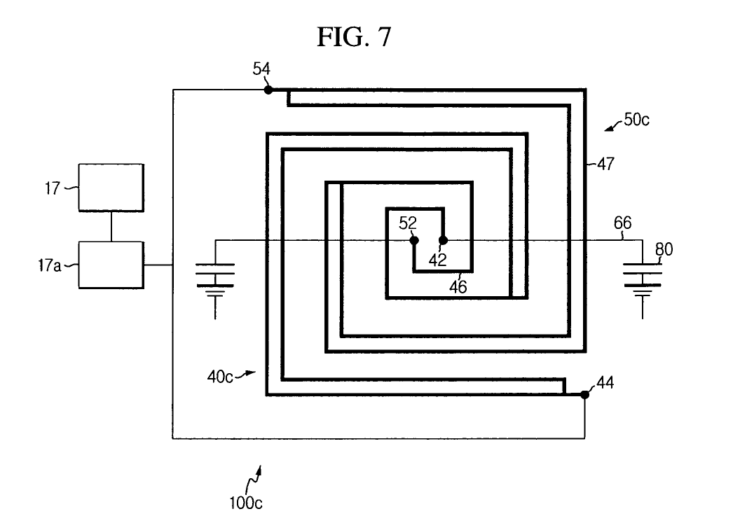

FIG. 6 is a plane view showing an antenna 100b according to a third embodiment of the present invention, and FIG. 7 is a plane view showing an antenna 100c according to a fourth embodiment of the present invention. As shown in FIG. 6, first and second antenna elements 40b, 50b are rotated in the same direction, but they are crossed with each other at some positions.

The antenna 100b, 100c is composed of first and second antenna elements 40b and 50b, 40c and 50c, and a ground terminal 42, 52 of each of the antenna elements 40b and 50b, 40c and 50c is positioned in a center portion of the antenna 100b, 100c, and grounded. In addition, a powered terminal 44, 54 of each of the antenna elements 40b and 50b, 40c and 50c is positioned in peripheral portions of the antenna 100b, 100c, and connected to a RF power source 17. Meanwhile, in FIGS. 6 and 7, the same reference numeral as in FIGS. 1 to 5 designates the same component having the same function.

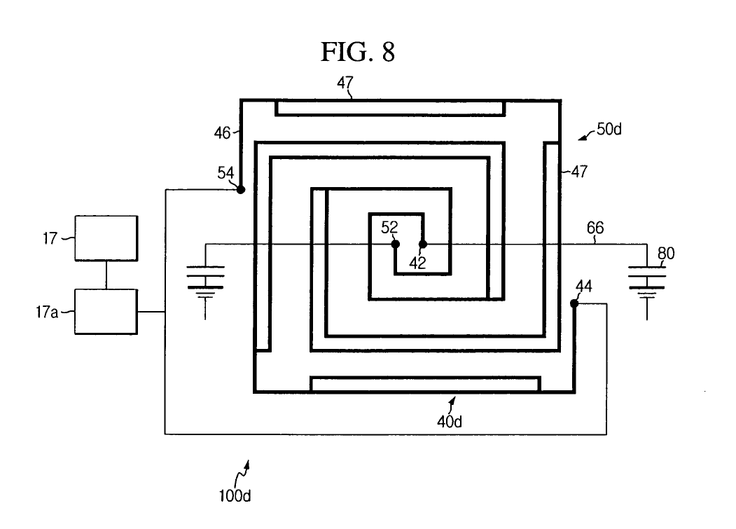

FIG. 8 is a plane view showing an antenna 100d according to a fifth embodiment of the present invention. In this antenna 100d, first and second antenna elements 40d, 50d becomes a serial region 46 in peripheral portions. In addition, powered terminals 44, 54 are positioned in the sides of antennas 100d.

If peripheral portions of the antenna 100d become a serial region 46 and the powered terminals 44, 54 are positioned in the sides of antennas 10d, an intensity of magnetic field is increased due to strengthened current.

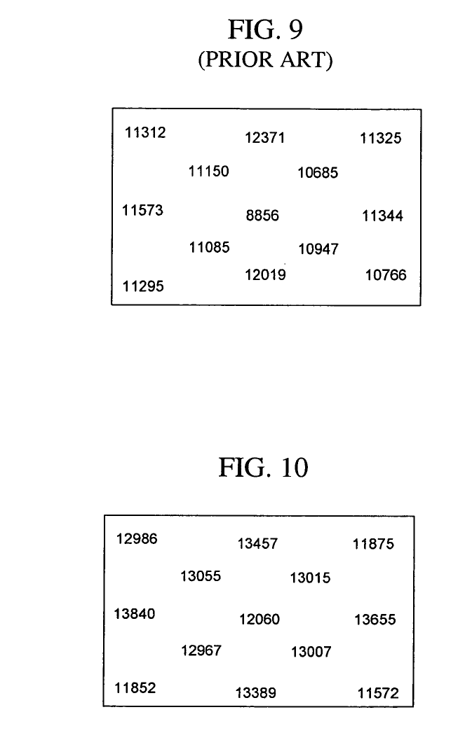

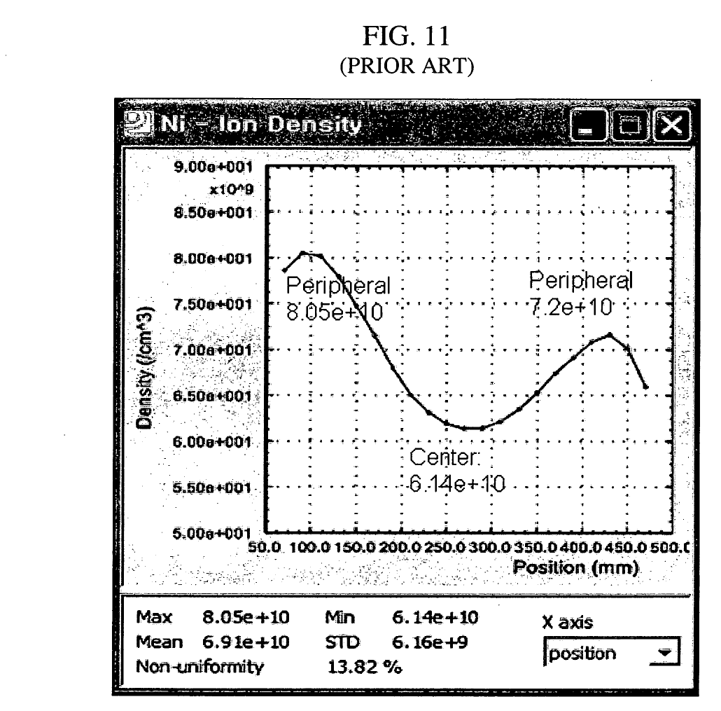

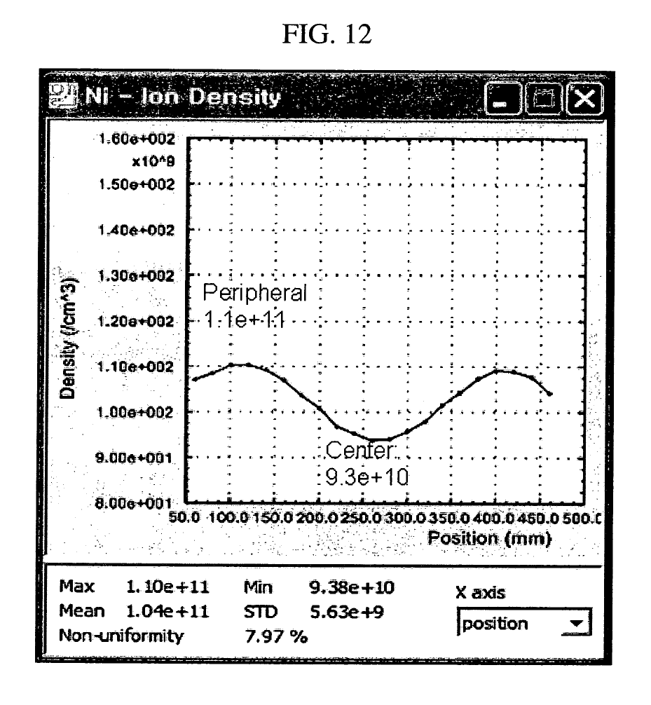

FIGS. 9 and 10 show an etch rate and a plasma density distribution in case of etching a glass using the conventional plasma generator 10, while FIGS. 10 and 12 shows an etch rate and a plasma density distribution in case of etching a glass using the plasma generator 100 according to the present invention. In the above experiment, the RF power source 17 has 2500 W, the bias power is 500 W, and HVDC is 2.2 KV. A used reaction gas is O₂ 300 sccm, a pressure is 10 mmTorr, and a wall temperature is 40° C. A used glass has a size of 370×470 mm. Results obtained in the above experiment are shown in the following Tables 1 and 2.

TABLE 1
Measurement data of photo register etch rate

| | Conventional plasma | Plasma generator of this |
|---|---|---|
| Etch rate (Å/min) | generator (10) | invention (100) |
| Max | 12,371 | 13,840 |
| Min | 8,856 | 11,572 |
| Average | 11,132 | 12,902 |
| Uniformity deviation | 16.6% | 7.7% |

TABLE 2
Measurement data of plasma ion density (Ni) at 20 mm distance
vertically from substrate surface

| Plasma ion | Conventional plasma | Plasma generator of this |
|---|---|---|
| density (Ni) | generator (10) | invention (100) |
| Max | 8.05e¹⁰ | 1.10e¹¹ |
| Min | 6.14e¹⁰ | 9.30e¹⁰ |
| Average | 6.91e¹⁰ | 1.04e¹¹ |
| Uniformity deviation | 13.82% | 7.97% |

As seen from Tables 1 and 2, in the conventional plasma generator 10, an etch rate in the center portion is smaller than that in the peripheral portions, and a plasma density in the center portion is smaller than that in the peripheral portions. However, it would be understood that differences of etch rates and plasma densities in the center portion and the peripheral portions plasma densities of the plasma generator 100 according to the present invention are decreased.

### APPLICABILITY TO THE INDUSTRY

The rectangular planar-type ICP antenna having a balanced ratio of a magnetic field and an electric according to the present invention gives the following effects.

First, it is possible to improve uniformity of plasma and uniformity of electron temperature in the center portion and the peripheral portions by grounding the ground terminals of the first and second antenna elements, connecting the RF power source to the powered terminals, arranging the ground terminal in the center portion of the antenna, and arranging the powered terminal in the peripheral portions of the antenna.

Second, by installing a capacitor to the first and second antenna elements or the ground strip, a voltage applied to the antenna becomes uniform, and a phase difference of current and voltage may be minimized.

1. The rectangular A planar-type ICP (Inductively Coupled Plasma) antenna having a balanced ratio of a magnetic field and an electric potential, comprising:
a first antenna element spirally shaped outwards from an end thereof; and
a second antenna element spirally shaped outwards from an end thereof,
wherein the ends of the fist and second antenna elements are interconnected by means of a grounded common terminal that is grounded by a ground strip,
wherein a RF (Radio Frequency) power source is connected to a powered common terminal for connecting first and second powered terminals that are the other ends of the first and second antenna elements, and
wherein the first and second powered terminals are arranged in peripheral portions of the antenna and the grounded common terminal is arranged in a center portion of the antenna in order to compensate for a drop of plasma ion flux in a region to which power is applied.

2. The rectangular A planar-type ICP antenna having a balanced ratio of a magnetic field and an electric potential, comprising:
a first antenna element spirally shaped outwards from a first ground terminal that is an end thereof; and
a second antenna element spirally shaped outwards from a second ground terminal that is an end thereof,
wherein the first and second ground terminals are respectively grounded by means of a ground strip,
wherein a RF power source is connected to a powered common terminal for connecting first and second powered terminals that are the other ends of the first and second antenna elements, and
wherein the first and second powered terminals are arranged in peripheral portions of the antenna and the first and second ground terminals are arranged in a center portion of the antenna in order to compensate for a drop of plasma ion flux in a region to which the RF power source is applied.

3. The rectangular planar-type ICP antenna according to claim 1,
wherein a capacitor is installed to the ground terminal so as to make an electric potential energy applied to the entire antenna uniform and optimize a phase difference of current and voltage.

4. The rectangular planar-type ICP antenna according to claim 1,
wherein the ground strip is perpendicular to a plane formed by the first and second antenna elements, and the ground strip is connected to a ground strip of an impedance matching circuit or a ground strip of a chamber wall.

5. The rectangular planar-type ICP antenna according to claim 1,
wherein the first and second antenna elements respectively have a plurality of serial regions and a plurality of parallel regions.

6. The rectangular planar-type ICP antenna according to claim 1,
wherein the peripheral portions are changed into a serial region at corners of the antenna.

7. The rectangular planar-type ICP antenna according to claim 1,
wherein the powered terminals are positioned at sides of the antenna.
